(19) United States
(12) Patent Application Publication
(10) Pub. No.: US 2014/0209951 A1
(43) Pub. Date: Jul. 31, 2014

(54) OXETANE-CONTAINING COMPOUNDS AND COMPOSITIONS THEREOF

(71) Applicants: HENKEL IP & HOLDING GMBH, Duesseldorf (DE); HENKEL AG & CO. KGAA, Duesseldorf (DE)

(72) Inventors: Shengqian Kong, Hillsborough, NJ (US); Puwei Liu, San Marcos, CA (US); Stijn Gillissen, Hasselt (BE); Donghang Xie, San Diego, CA (US); Lirong Bao, Hillsborough, NJ (US); Daniel J. Duffy, Naperville, IL (US); Allison Yue Xiao, Belle Mead, NJ (US); Emilie Barriau, Laguna Niguel, CA (US)

(73) Assignees: HENKEL IP & HOLDING GMBH, Duesseldorf (DE); HENKEL AG & CO. KGAA, Duesseldorf (DE)

(21) Appl. No.: 14/228,348

(22) Filed: Mar. 28, 2014

Related U.S. Application Data
(63) Continuation of application No. PCT/US2012/057267, filed on Sep. 26, 2012.
(60) Provisional application No. 61/540,097, filed on Sep. 28, 2011.

(51) Int. Cl. H01L 33/56; H01L 33/60; H01L 33/50; H01L 33/58

(52) U.S. Cl. CPC H01L 33/56; H01L 33/58; H01L 33/60; H01L 33/50
USPC 257/98; 528/194; 528/361; 528/176; 528/112; 252/301.36

(57) ABSTRACT

Oxetane-containing compounds, and compositions of oxetane-containing compounds together with carboxylic acids, latent carboxylic acids, and/or compounds having carboxylic acid and latent carboxylic acid functionality are provided. The oxetane-containing compounds and compositions thereof are useful as adhesives, sealants and encapsulants, particularly for components, and in the assembly, of LED devices.

### CROSS-REFERENCE TO RELATED APPLICATION

This application claims the benefit of U.S. Provisional Patent Application No. 61/540,097 filed Sep. 28, 2011, the contents of which are incorporated herein by reference.

### BACKGROUND

1. Field

Oxetane-containing compounds, and compositions of oxetane-containing compounds together with carboxylic acids, latent carboxylic acids, and/or compounds having carboxylic acid and latent carboxylic acid functionality are provided. The oxetane-containing compounds and compositions thereof are useful as adhesives, sealants and encapsulants, particularly for components, and in the assembly, of LED devices.

2. Brief Description of Related Technology

Light emitting diodes (“LEDs”), particularly those of the high power or high brightness variety, are gaining momentum in lighting and light energy generation applications, as a replacement for incandescent and fluorescent lamps for retail use, architectural illumination, automotive use, and street lighting.

Encapsulant materials are used in LED fabrication to provide barrier protection against sulfuric compounds, nitrogen oxides, moisture and oxygen. Of these, protection against sulfuric compounds is especially important because LEDs used as head or tail lights on automobiles are exposed to sulfuric compounds from tires and other sources in the environment. Sulfuric compounds, such as hydrogen sulfide gas, can permeate the LED encapsulant and react with any silver-plated lead-frame surfaces in the LED package, thereby changing the plated silver to silver sulfide. This results in blackening the silver-plated surface, which can cause significant reduction in light output of the LED device.

Encapsulant materials also aid in light extraction. The refractive index (n) of most LED semiconductor materials is quite high (e.g., n≈2.5 for GaN LEDs and n≈3.0 for AlGaInP LEDs); this means that a significant amount of light will be reflected back into the semiconductor material at the material/air interface (n=1 for air), resulting in a noticeable loss in LED efficiency. Commercial LED encapsulants typically have a refractive index in the range of 1.41-1.57, intermediate between the semiconductor material and air, and consequently allowing more light to get extracted out of the semiconductor material and into the air. High refractive index, non-yellowing encapsulant materials (n>1.6) would be an advantage for efficient light extraction.

Heat resistant polymers and/or polymer composites are used as encapsulant materials, and are known to maintain mechanical properties (modulus, elongation, toughness, adhesive strength) under thermal aging conditions. These are important for LED applications, but without good optical transparency under continuous usage, the polymers are nevertheless unsuitable.

Traditionally, epoxies have been used as an encapsulant material for this application because they have low moisture permeability, high refractive index, high hardness, and low thermal expansion. However, epoxies turn yellow after exposure to photon fluxes and temperatures at about 100° C. Due to high electricity consumption, LEDs can reach operating temperatures as high as 150° C.; consequently, light output from LEDs is significantly affected when epoxies are used.

Silicone based materials are known to withstand high temperature and photon bombardment without developing yellow coloration. However, silicones ordinarily show poor moisture barrier properties, adhesion and mechanical properties. Polymethacrylates and polycarbonates also have reasonable optical stability under thermal aging, but being thermoplastic in nature these materials tend to creep when used above their glass transition temperatures compromising their usefulness in such applications.

Oxetanes are also known, though they have not been used for sealing or encapsulating LEDs. The ring-opening polymerizations of oxetanes using cationic or anionic catalysts are known to result in polyether structures, which have poor stability, oxidize, and turn Ed., yellow (Z W Wicks, et al., Organic Coatings: Science and Technology, 3^{rd} Ed. John Wiley & Sons, Inc., 99 (2007). Polyesters generally have better thermal and photo stability than polyethers, and can be obtained through co-polymerization of oxetanes with anhydrides. However, the co-polymerization of oxetanes with anhydrides is affected by the catalyst used. In many cases, the reaction gives a polyester-polyether copolymer, which is undesirable due to the presence of ether linkages having hydrogens susceptible to oxidation, such as those on —CH₂—O—CH₂—. Pure polyesters are obtained only when certain onium salts are used as catalysts. Onium catalysts cause yellowing; also they contain halide anions, which cause potential corrosion, making them undesirable where clarity, cosmetics and/or transmittance are desirable properties.

It would be advantageous to provide curable compositions having improved sealant and encapsulant properties while maintaining excellent optical characteristics in high temperature applications, such as for LEDs and photovoltaic devices, that balance optimal mechanical properties with the preservation of optical clarity after thermal aging.

### SUMMARY

Compositions of oxetane-containing compounds together with carboxylic acids, latent carboxylic acids and/or compounds having carboxylic acid functionality and latent carboxylic acid functionality are provided, which are useful as adhesives, sealants and encapsulants, particularly for components of and in the assembly of LED devices. The oxetane-containing compounds may be used individually or in combination. To that end, the oxetane-containing compounds may be mono-functional oxetanes or multi-functional oxetanes. Here, multi-functional connotes two or more; that is, two or more oxetane functional groups. When used in combination, the oxetane-containing compounds may be the combination of two or more mono-functional oxetane-containing compounds, two or more multi-functional oxetane-containing compounds, or one or more mono-functional oxetane-containing compound(s) and one or more multi-functional oxetane-containing compound(s).

Of particular interest are oxetane-containing compounds which are oxetane esters or oxetane ethers.

For instance, mono- or multi-functional aliphatic or aromatic oxetane ester resins embraced by the following general structure, in which R is a methyl or ethyl group and n is 1 to 6 are particularly desirable.

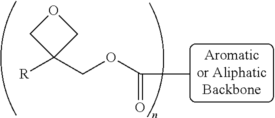

More specifically, aromatic oxetane esters may be embraced by the following general structure, in which R is a methyl or ethyl group and Ar is an aromatic group:

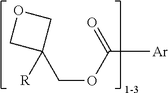

### BRIEF DESCRIPTION OF THE FIGURES

FIG. 1 depicts a cross sectional view of a LED device.

FIG. 2 depicts an exploded perspective view of a LED device in which the fluorescent material is disposed in a position remote from the LED.

FIG. 3 depicts a plot of transparency at 450 nm of the noted compositions after ageing at 150° C.

### DETAILED DESCRIPTION

The curable compositions may be used as sealants or encapsulants such as to mold and seal electronic devices and to provide barrier protections for these devices. The curable compositions can be used in any area of the electronic device for sealing or encapsulation, such as for sealing or encapsulating LEDs.

The oxetane-containing compound which forms part of the composition may be an aliphatic oxetane-containing compound or an aromatic oxetane-containing compound. The oxetane-containing compound may have at least one oxetane ester functional group attached to an aromatic substrate or an aliphatic substrate. In some cases, the oxetane-containing compound may also have carboxylic acid functionality or latent carboxylic acid functionality as well. In the case of the carboxylic acid functionality, an aromatic carboxylic acid or an aliphatic carboxylic acid may be present. In the case of the latent carboxylic acid functionality, an aromatic latent carboxylic acid or an aliphatic latent carboxylic acid may be present. The latent carboxylic acid may be an aliphatic anhydride or an aromatic anhydride.

As noted above, the oxetane-containing compounds include aliphatic or aromatic oxetane ester resins embraced by the following general structure, in which R is a methyl or ethyl group and n is 1 to 6.

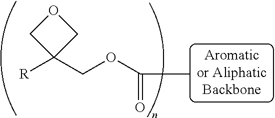

More specifically, aromatic oxetane esters may be embraced by the following general structure, in which R is a methyl or ethyl group and Ar is an aromatic group:

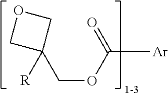

Ar may be any aromatic group with its carbon to carbon double bonds in conjugation with the carbon to oxygen double bond of the ester group.

In some embodiments, Ar is a single aryl group, two fused aryl groups, or two or more aryl groups connected by a direct bond, a lower alkylene (such as a one to four carbon atom alkylene linkage), or a heteroatom, such as oxygen or sulfur.

In other embodiments, Ar is two or more aryl groups connected by a linking group selected from

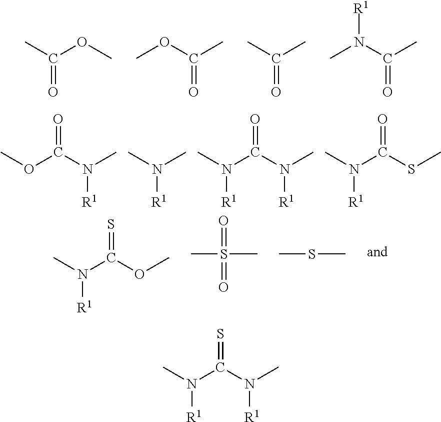

in which R¹ is a lower alkyl group (where lower is as exemplified above).

In one embodiment, oxetane ester functionalities are attached to an aliphatic backbone selected from linear, branched, or cycloalkylene groups, which optionally contain heteroatoms (such as O, S, halogens, Si, and N) or aromatic interruptions or substitutions.

In another embodiment, oxetane ester functionalities are attached to an aromatic backbone with its carbon to carbon double bonds in conjugation with the carbon to oxygen double bond of the ester group.

Oxetane-containing compounds suitable for use herein include:

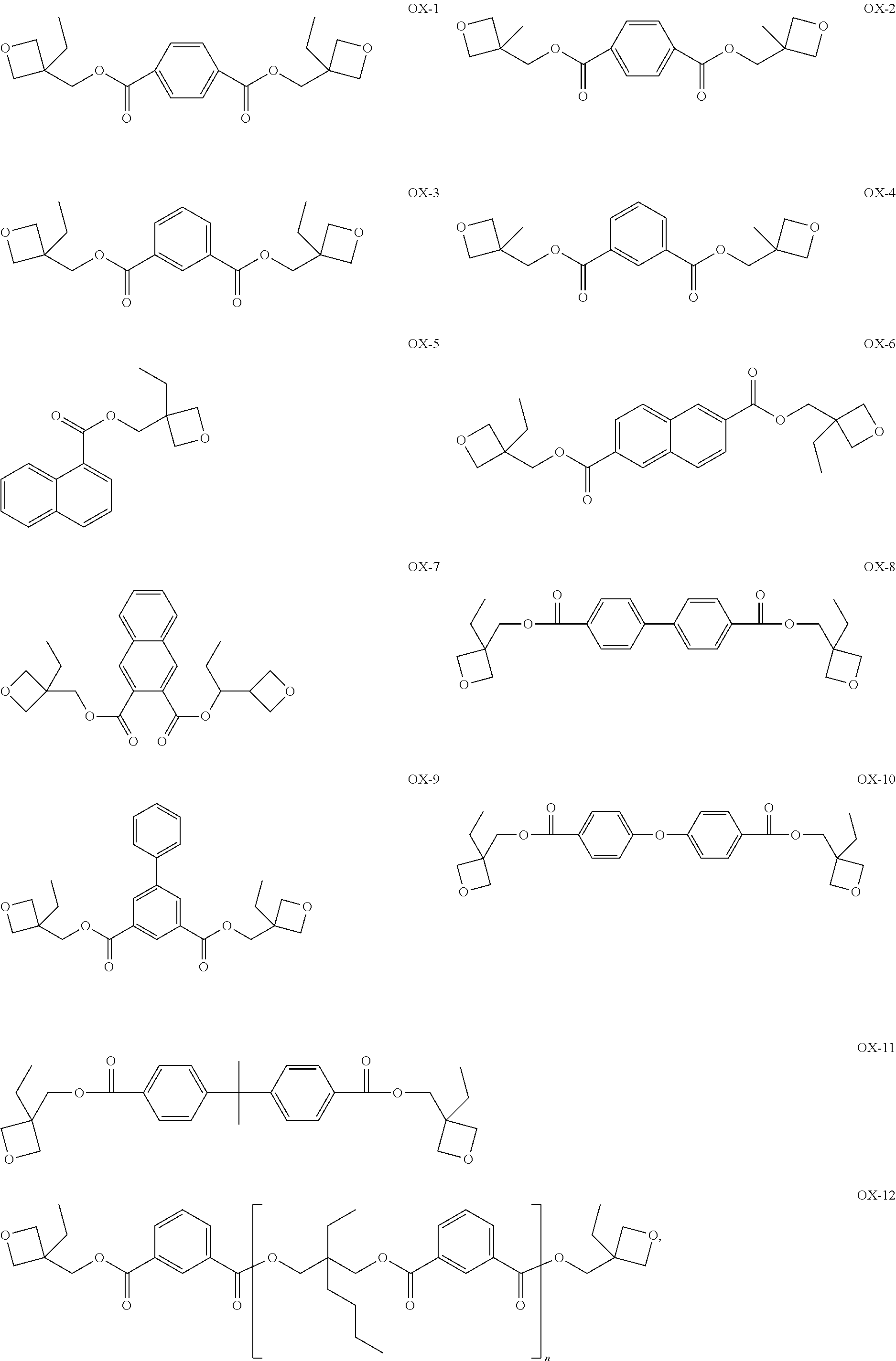

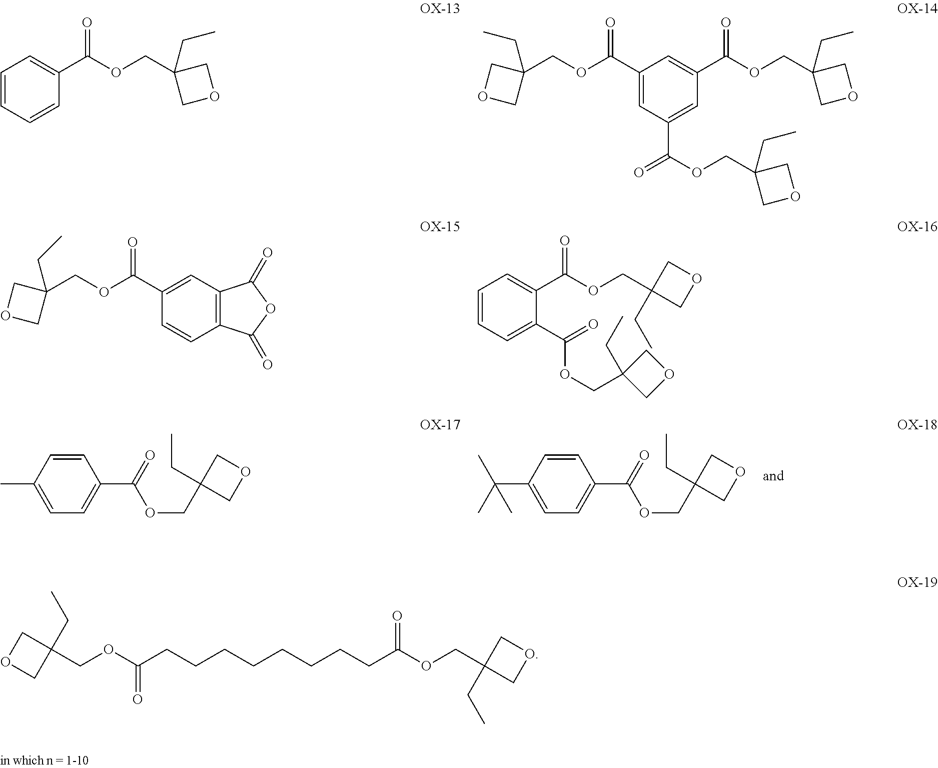

Either a methyl group or an ethyl group may be attached to the carbon in the 3 position on the oxetane ring. Where one group is shown, the other group may be substituted.

It may be desirable to introduce the oxetane by way of polymeric or elastomeric resin. In such a situation, the oxetane or oxetane ester functionalities are present at terminus of and/or as pendant groups on, a polymeric backbone. Representative polymer backbones include, but are not limited to, poly(meth)acrylates, polyolefins, polystyrene, polyesters, polyimides, polycarbonates, polysulfones, polysiloxanes, polyphosphazenes, and novolac resins.

In one embodiment, the oxetane-containing compounds are selected from OX-1, OX-2, OX-3, and OX-4.

In another embodiment, in which a high RI of at least about 1.5, such as at least about 1.55, desirably about 1.6, may be a desirable feature, the oxetane-containing compounds are selected from OX-5, OX-6, OX-7, OX-8 and OX-9. A lower or normal RI, such as would ordinarily be found in dialkyl siloxane based silicone materials, is typically in the range of about 1.41-1.42.

Certain oxetane-containing compounds also provided. For instance

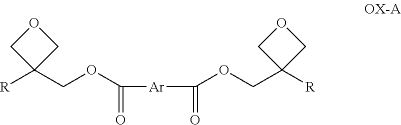

where for OX-A R generally is methyl or ethyl, and Ar generally is an aromatic ring or aromatic ring system. More specifically, when Ar is a phenyl ring with ortho substitution, R is methyl or ethyl; when Ar is a phenyl ring with meta substitution, R is methyl; when Ar is biphenyl with meta or para substitution, R may be methyl or ethyl; when Ar is the backbone of a bisphenol A, E, F or S, R may be methyl or ethyl; Ar is a polymeric structure with repeating units of an aromatic polyester (such as is shown in OX-12) or Ar is a phenyl ether, provided that Ar is not para substituted and with R being methyl or ethyl.

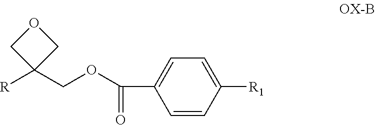

where for OX-B R generally is methyl or ethyl, and R₁ is an alkyl group of one to four carbon atoms, such as methyl, ethyl, propyls or butyls, particularly t-butyl.

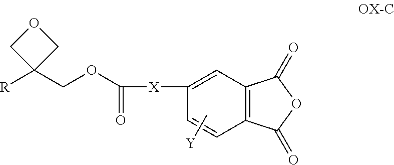

where for OX-C R is a methyl or ethyl group, X is a direct bond, or a linear or branched alkanediyl group with or without substitution by heteroatom, and Y is selected from an aryl, alkyl, alkoxy and thioalkoxy, cyano, nitro group, or a hetero atom.

Referring back to OX-C and more specifically OX-15, these oxetane/anhydride hybrid compounds may be curable under the cure conditions described herein, with the presence of an alcohol and desirably a catalyst, such as a cationic catalyst.

Carboxylic acids, such as aromatic carboxylic acids having the general formula Ar—COOH, may be used with the oxetane-containing compounds in the curable compositions. Ar on the aromatic carboxylic acid is any aromatic group with its carbon to carbon double bonds in conjugation with the carbon to oxygen double bond of the carboxylic acid group. In some embodiments, the aromatic group is a single aryl group, or two fused aryl groups, or two or more aryl groups connected by a direct bond, a lower alkylene (such as a one to four carbon atom alkylene linkage), or a heteroatom, such as oxygen or sulfur.

In other embodiments, the two or more aryl groups are connected by a linking group selected from

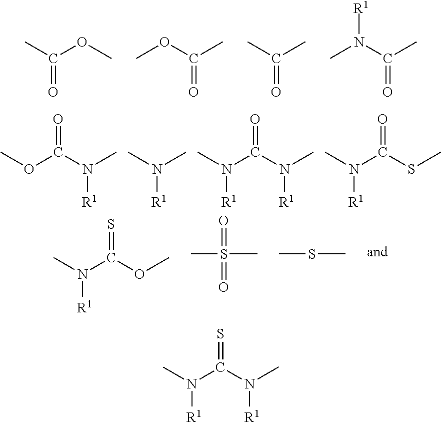

in which R¹ is a lower alkyl group.

Exemplary carboxylic acids include but not limited to benzoic acid, terephthalic acid, phthalic acid, isophthalic acid, 1,2,4-benzenetri-carboxylic acid, trimesic acid, naphthoic acid, isomers of naphthalene-dicarboxylic acid and an adduct of TMAn and a diol.

Latent carboxylic acids may be used with the oxetane-containing compounds in the curable compositions too. A representative example of the latent carboxylic acid is an anhydride. Example of suitable anhydrides include diesters of trimellitic anhydride, which are embraced by

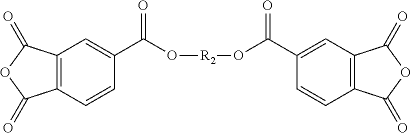

where R₂ is a linear or branched alkanediyl group. More specific examples of suitable anhydrides are:

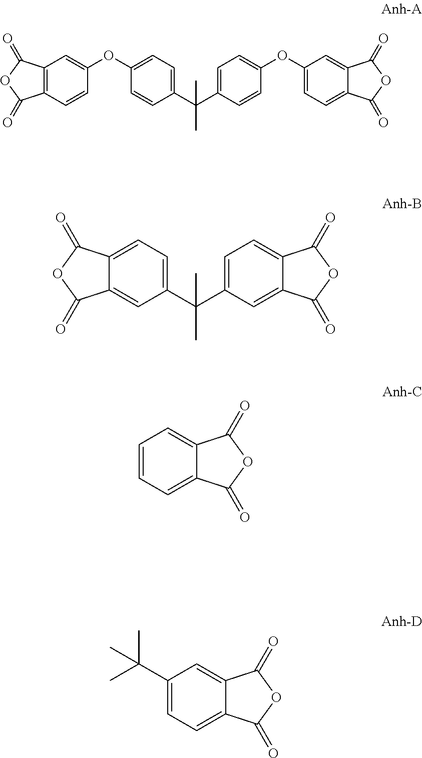 [SMILES: CC(C)(c1ccc(Oc2ccc3c(c2)C(=O)OC3=O)cc1)c1ccc(Oc2ccc3c(c2)C(=O)OC3=O)cc1 ; CC(C)(c1ccc2c(c1)C(=O)OC2=O)c1ccc2c(c1)C(=O)OC2=O ; O=C1OC(=O)c2ccccc21 ; CC(C)(C)c1ccc2c(c1)C(=O)OC2=O]

Other anhydrides that may be used depending on the properties sought in the curable composition include pyromellitic dianhydride, 4,4′-carbonyldiphthalic anhydride, 4,4′-sulfonyldiphthalic anhydride, 3,3′,4,4′-biphenyltetracarboxylic dianhydride, 4,4′-oxydiphthalic anhydride, and 4,4′-(hexafluoroisopropylidene)diphthalic anhydride, to name a few.

Or compounds having at least one carboxylic acid functionality and at least one latent carboxylic acid functionality, such as an anhydride group, on the same molecule, may be used. A desirable example is the aromatic carboxylic acid anhydride, trimellitic anhydride (“TMAn”), which is a solid at room temperature and has the following structure:

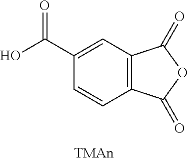 [SMILES: O=C(O)c1ccc2c(c1)C(=O)OC2=O]

Another desirable compound with carboxylic acid and latent carboxylic acid (e.g., anhydride) functionality has the structure:

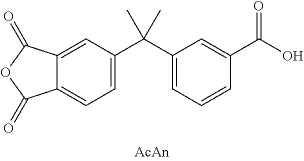 [SMILES: CC(C)(c1cccc(C(=O)O)c1)c1ccc2c(c1)C(=O)OC2=O]

The carboxylic acid or latent carboxylic acid may be present in the formulation as solid particles. Depending on the nature of the latent carboxylic acid the curable compositions can be either heterogeneous or homogeneous. In addition, the cured reaction product may be transparent.

The stoichiometric ratio of oxetane to carboxylic acid or latent carboxylic acid will be about 1:1, meaning that this ratio can vary so that either component is present in a slight excess. In some embodiments, for example, the ratio should be within the range of 0.7:1.3, and in other embodiments, the ratio should be within the range of 1.3:0.7. When both an carboxylic acid and a latent carboxylic acid are present (either as separate components or as functionality on the same compound), the sum of the acid and latent acid will constitute the same term in the ratio. That is, the ratio of oxetane to acid plus latent acid remains about 1:1.

In addition to the oxetane-containing compound and at least one of the carboxylic acid, the latent carboxylic acid, the compounds having at least one carboxylic acid functionality and at least one latent carboxylic acid functionality, or mixtures thereof, various antioxidants and light stabilizers, known to improve the thermal and light stability of reaction products of the curable compositions, can be added as determined by the practitioner. Detailed descriptions of such additives can be found in Z W Wicks, et al., Organic Coatings: Science and Technology, 3^{rd} Ed., John Wiley & Sons, Inc., 97-106 (2007).

Antioxidants include peroxide decomposers, such as sulfides and phosphites, which reduce hydroperoxides to alcohols and become oxidized into harmless products. Other antioxidants are metal complexing agents, such as bidentate imines, which act by trapping transition metals in complex form, making these metals unavailable for catalyzing oxidative degradation. Other antioxidants are chain breaking antioxidants, such as hindered phenols, which function by interfering directly with the chain propagation step of auto-oxidation.

Light stabilizers include UV absorbers, hindered amines, and nickel quenchers. UV absorbers function by preferentially absorbing harmful ultraviolet radiation and dissipating it as thermal energy; examples include benzophenones, benzotriazoles, phenol substituted trazines, and oxalanilides.

When present, antioxidants may be used in an amount ranging from 0.01 to 5% by weight. When present, light stabilizers may be used in an amount ranging from 0.01 to 5% by weight.

In one embodiment, the curable compositions may contain solvents, adhesion promoters, rheology modifiers, defoamers, catalysts (such as zinc-containing catalysts, bismuth-containing catalysts, tin-containing catalyst, and combinations thereof), alcohol compounds, co-reactants like oxiranes, thiiranes, and thiooxetanes or other additives known to those skilled in the art.

In some embodiments, fluorescent materials, such as phosphors, may be added to the curable composition to enhance the quality of light emission, more specifically, to change the light emitted from the LED from blue to white light. In order to emit white light, the wavelength of emission from the LED should be between 400 nm and 530 nm, such as 420 nm and 490 nm, in consideration of the complementary color relationship with the light emitted by the fluorescent material. In other embodiments, phosphors may be included in a setting remote from the LED itself. (See e.g. FIG. 2.) In such a situation, phosphors for instance may be dispersed in a substantially uniform manner throughout a matrix that has been cured. This consists of a phosphor composite layered onto a substrate, separated from the LED energy source. The phosphor emits light when excited by blue light.

Phosphors may be chosen from a host of materials. For instance, phosphors, which in this commercial application, absorb light emitted by a LED and convert it to light of a different wavelength, may be selected from among nitride fluorescent materials and oxynitride fluorescent material that is mainly activated with lanthanoid elements such as Eu and Ce; alkaline earth halogen apatitie fluorescent material that is mainly activated with lanthanoid elements such as Eu and transition metal elements such as Mn; alkaline earth metal halogen-borate fluorescent material; alkaline earth metal aluminate fluorescent material; rare earth element aluminate fluorescent material that is mainly activated with alkaline earth silicate, alkaline earth sulfide, alkaline earth thiogallate, alkaline earth silicon nitride, germanate, or lanthanoid elements such as Ce; and organic and organic complexes that are mainly activated with rare earth silicate or lanthanoid elements such as Eu.

Examples of the oxynitride fluorescent material that is mainly activated with lanthanoid elements, such as Eu and Ce, include M₂Si.₅N₈:Eu (where M represents Sr, Ca, Ba, Mg or Zn); M₂, Si₆, MSi₇N₁₀:Eu, M_{1.8}Si₅O_{0.2}N₈:EU and M₉Si₇O_{0.1}N₁₀:Eu (where M represents Sr, Ca, Ba, Mg or Zn).

Examples of the acid nitride fluorescent material that is mainly activated with lanthanoid elements, such as Eu and Ce, include MSi₂O₂N₂:Eu (where M represents Sr, Ca, Ba, Mg or Zn).

Examples of the alkaline earth halogen apatite fluorescent material that is mainly activated with lanthanoid elements, such as E, and transition metal elements, such as Mn, include M₅, (PO₄,)₃ₓ:R (where M represents Sr, Ca, Ba, Mg or Zn, X represents a halogen, and R represents Eu, Mn, Eu or Mn).

Examples of the alkaline earth metal halogen-borate fluorescent material include M₂B₅O₉ₓ:R (where M represents Sr, Ca, Ba, Mg or Zn, X represents a halogen, and R represents Eu, Mn, Eu or Mn).

Examples of the alkaline earth metal aluminate fluorescent material include SrAl₂, O₄:R, Sr₄Al₁₄O₂₅:R, CaAl₂O₄:R, BaMg₂Al₁₆O₂₇:R, BaMg₂Al₁₆O₁₂:R and BaMgAl₁₀,O₁₇:R (where R represents Eu, Mn, Eu or Mn).

Examples of the alkaline earth sulfide fluorescent material include La₂O₂S:Eu,Y₂O₂S:Eu and Gd₂,O₂,S:Eu.

Examples of the rare earth aluminate fluorescent material that is mainly activated with lanthanoid elements, such as Ce, include YAG fluorescent materials represented by the formulas: Y₃Al₅O₁₂:Ce (Y_{0.8}Gd_{0.2})₃Al₅O₁₂:Ce, Y₃ (Al_{0.8}Ga_{0.2})₅O₁₂:Ce and (Y, Gd)₃(Al, Ga)₅O₁₂. It also includes Tb₃Al₅O₁₂:Ce and Lu₃Al₅O₁₂:Ce in which portion or all of Y is substituted with Tb or Lu.

Example of the other fluorescent material include ZnS:Eu, Zn₂GeO₄:Mn and MGa₃S₄:Eu (where M represents Sr, Ca, Ba, Mg or Zn, and X represents a halogen).

If desired, these fluorescent materials can contain at least one element selected from among Tb, Cu, Ag, Au, Cr, Nd, Dy, Co, Ni and Ti, in place of Eu, or in addition to Eu.

The Ca—Al—Si—O—N oxynitride glass fluorescent material is a fluorescent material composed mainly of an oxynitride glass comprising 20 to 50 mol % of CaCO₃ based on CaO, 0 to 30 mol % of Al₂O₃, 25 to 60 mol % of SiO, 5 to 50 mol % of AlN, 0.1 to 20 mol % of rare earth oxide or transition metal oxide, the total content of five components being 100 mol %. In the fluorescent material composed mainly of the oxynitride glass, the nitrogen content is preferably 15% by weight or less, and the fluorescent glass preferably contains, in addition to rare earth element ions, 0.1 to 10 mol % of other rare earth element ions in the form of rare earth oxide as a coactivator.

Various polymer or inorganic particles (other than fluorescent materials) may be used in the curable compositions to achieve specific purposes. For example, particles with a refractive index matching that of the encapsulant may be used to accomplish transparency; particles with a refractive index higher than that of the encapsulant (such as titanium oxide, potassium titanate, zirconium oxide, zinc sulfide, zinc oxide, or magnesium oxide) may be used to achieve good reflectivity or whiteness. Electrically or thermally conductive particles may be added to improve electrical or thermal performances. In addition to conventional particles, nano-sized particles may also be incorporated.

In other embodiments, an LED or a photovoltaic device sealed or encapsulated with reaction products of the curable compositions described herein is also provided.

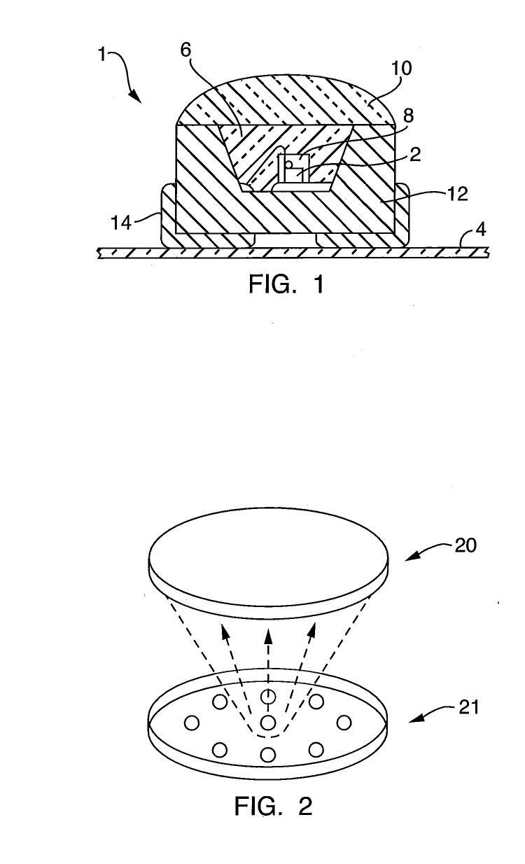

With reference to FIG. 1, the LED device 1 includes a LED 2, which may be one or more semiconductor materials, constructed from, for instance, silicon, silicon carbide, gallium nitride and/or other semiconductor materials, a substrate 4 which may comprise sapphire, silicon, silicon carbide, gallium nitride or other microelectronic substrates, and one or more contacts disposed on a substrate which may comprise metal and/or other conductive layers. In addition, a substantially transparent encapsulant 6 formed from the reaction product of the curable composition is disposed on, over and/or about the LED 2 so that it provides a barrier or covering thereover. And a fluorescent material 8 that absorbs at least part of light emitted by the LED 2 and converts it to light of a longer wavelength may be ordinarily disposed over the LED 2 and between the LED 2 and the encapsulant 6. In this way, the fluorescent material 8 is excited with the light emitted by the LED 2 to emit light of a color different from that of the light emitted by the LED 2. The fluorescent material 8 may also be dispersed in the substantially transparent encapsulant 6.

Optionally, a separate lens 10 that changes the direction of light emission from the LED 2 and/or the fluorescent material 8 may be disposed over the encapsulant 6. The lens 10 should be of a substantially semi-cylindrical shape with a convex side extending outward from the device. Or the encapulsant 6 may itself be shaped with convex curvature so as to act as a lens.

The LED device may also optionally include a reflector 12 to direct and focus the light emitted from the LED 2 outward, such as toward the lens. The reflector 12 is an element that is dimensioned and disposed to be positioned around, such as radially around, the LED. The reflector 12 may also be formed from the reaction product of a curable composition together with a reflective material. The LED device may be attached to lead frame 14, all of which is then mounted on substrate 4.

In the event the lens is made from a different material, the lens should have a higher durameter (harder) than the curable composition used to encapsulate the LEDs and bondwires. The lens should have high light transmissivity and a RI that matches to at least a large extent that of the curable composition used as an encapsulant, such that minimal light will be reflected by total internal refraction (“TIR”), and have a substantially similar coefficient of thermal expansion (“CTE”) as the encapsulant.

Where the fluorescent material is included in the curable composition, it should be distributed with a higher concentration in a region near the surface of the LED than in a region near the surface of the portion that is located proximate the lens or which constitutes the lens.

With reference to FIG. 2, the fluorescent material 20 may be disposed in a location distil from the LED device 21, as noted above. In what is termed a “remote phosphor” design, a phosphor composite layered onto a substrate is separated from the LED energy source. The phosphor emits light when excited by blue light.

In another embodiment a method of manufacturing an encapsulant composition for an LED assembly is provided. The steps of the method include
providing one or more oxetane-containing compounds; and
providing at least one of an carboxylic acid, a latent carboxylic acid, compounds having at least one carboxylic acid functionality and at least one latent carboxylic acid functionality, or mixtures thereof, and
combining with mixing the an oxetane-containing compound and the at least one of an carboxylic acid, a latent carboxylic acid, compounds having at least one carboxylic acid functionality and at least one latent carboxylic acid functionality, or mixtures thereof.

The so-formed encapsulant composition when cured at a temperature of 25° C. to 200° C., such as 80° C. to 175° C., for a period of time of about 1 to about 2 hours demonstrates an initial transparency of at least about 85% and a percent transparency decrease of about 10% after exposure to a temperature of 150° C. for a period of time of 1,000 hours as measured by UV/VIS spectrophotometer at 450 nm; thermal stability after exposure to 150° C. for a period of time of 500 hours in terms of yellowing of less than 10 as measured by BYK CIE spectro-guide or a percent transmission decrease of less than about 10%, such as about less than about 5%; has a refractive index of greater than 1.5; and barrier properties of less than 2 g*cm/[m²*day] measured by water vapor transmission rates at 50° C. at a relative humidity of 100% using a MOCON PERMATRAN-W-3/33. The percent transparency decrease of the cured encapsulant composition is measured after exposure to a temperature of 150° C. for a period of time of 1,000 hours.

Traditionally, manufacturers of LED devices have used either epoxy-containing or silicone-containing encapsulants. Toward the end of the examples, representative commercial encapulsants based on these two chemistries are set forth for comparative purposes.

In the following examples, the yellowness index is a number calculated from spectrophotometric data that describe the change in color of a test sample from clear or white toward yellow. This test is most commonly used to evaluate color changes in a material caused by real or simulated outdoor exposure. The yellowness index is defined by ASTM E313. The BYK CIE spectro-guide was used for the test, and the yellowness index of the standard BYK white background card was 6.33. Film samples having a yellowness index value lower than 6.33 were deemed to be non-yellow.

### EXAMPLES

### Syntheses of Oxetane-Containing Compounds

### Example 1

### Bis[(3-methyl-3-oxetanyl)methyl]isophthalate

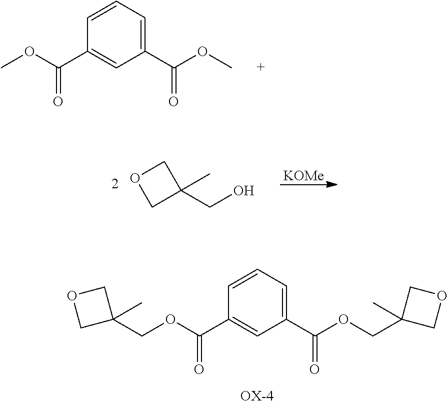

To a 200 mL flask was added 50 g of 3-methyl-3-oxetanemethanol, followed by a solution of 0.1 g of KOMe dissolved in 2 mL methanol. Next, 38.8 g of dimethyl isophthalate was added and the mixture heated at a temperature of 70° C. until dissolution. The mixture was heated for a period of time of two hours at a temperature of 70° C. under vacuum. A slightly yellow powder was observed to have formed. The powder was recrystallized from 100 mL of toluene, affording 25.0 g of a white powder with melting point of 108° C. in a 37% yield.

The title compound was characterized by NMR: ¹H NMR (CDCl₃, 250 MHz), δ (ppm): 8.71 (1H), 8.28-8.26 (2H), 7.59-7.56 (1H), 4.64-4.63 (4H), 4.48-4.45 (8H), 1.44 (6H).

### Example 2

### 3-Ethyl-3-oxetanylmethyl 1-naphthoate

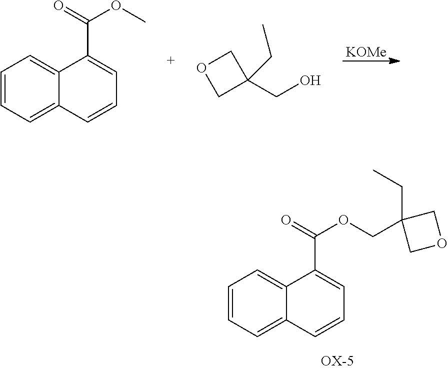

A procedure similar to that which is set forth in Example 1 was used to synthesize 3-ethyl-3-oxetanylmethyl 1-naphthoate, except methyl 1-naphthoate (“TCI”) and 3-ethyl-3-oxetanemethanol (“TMPO”) were used as starting materials. The title compound was afforded in a 97% crude yield as a yellow liquid. Recrystallization from 2-propanol provided a needle-like white crystal with a melting point of 62° C. and a RI of 1.6285.

The title compound was characterized by NMR: ¹H NMR (CDCl₃, 250 MHz), δ (ppm): 8.96-8.92 (1H), 8.22-8.19 (1H), 8.04-8.00 (1H), 7.90-7.86 (1H), 7.65-7.46 (3H), 4.65-4.62 (2H), 4.57-4.49 (4H), 1.92-1.83 (2H), 1.03-1.00 (3H).

### Example 3

### Bis [(3-ethyl-3-oxetanyl)methyl] 2,6-naphthalenedicarboxylate

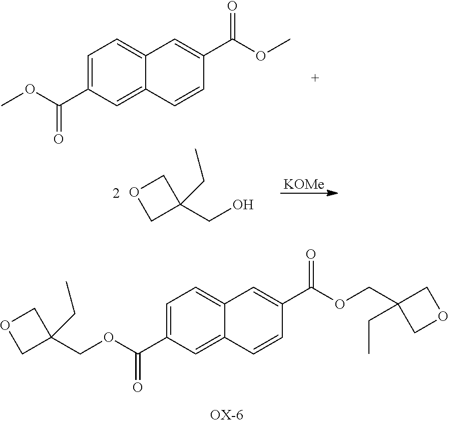

To a 500 mL flask was added 24.4 g of dimethyl 2,6-naphthalenedicarboxylate, followed by 100 ml toluene and 150 ml of dimethyl carbonate. Over time, the sample dissolved at a temperature of 90° C. Next, 30 g of TMPO was added, and solvents removed under a modestly elevated temperature and reduced vacuum. A solution of 0.1 g of KOMe dissolved in 3 g of methanol was added. Next, vacuum was applied to the reaction at 90° C. to remove methanol. The reaction mixture turned slightly yellow and became a liquid, which solidified upon standing. The resulting solid was recrystallized in a toluene/dimethyl carbonate solvent mixture and dried, affording 27.0 g of a white powder with a melting point of 135° C. in a 66% yield.

The title compound was characterized by NMR: ¹H NMR (CDCl₃, 250 MHz), δ (ppm): 8.64 (2H), 8.16-8.01 (4H), 4.66-4.64 (4H), 4.54-4.52 (8H), 1.95-1.86 (4H), 1.04-0.98 (6H).

### Example 4

### BisH3-ethyl-3-oxetanyl)methyl] 2,3-naphthalenedicarboxylate

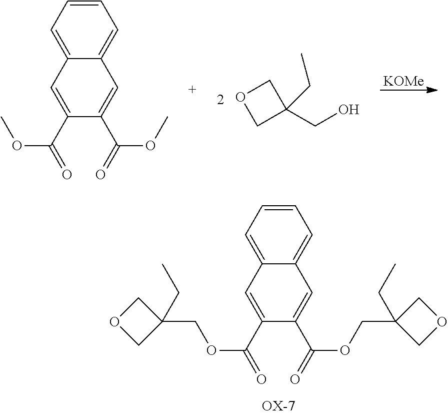

A procedure similar to Example 3 was used to make bis[(3-ethyl-3-oxetanyl)methyl]2,3-naphthalenedicarboxylate. The title compound was afforded as an off-white powder with a melting point of 70° C. and an RI of 1.5657.

The title compound was characterized by NMR: ¹H NMR (CDCl₃, 250 MHz), δ (ppm): 8.27 (2H), 7.97-7.92 (2H), 7.67-7.63 (2H), 4.62-4.61 (4H), 4.52 (4H), 4.49-4.48 (4H), 1.88-1.83 (4H), 1.02-0.98 (6H).

### Example 5

### Bis[3-ethyl-3-oxetanyl)methyl]biphenyl-3,5-dicarboxylate

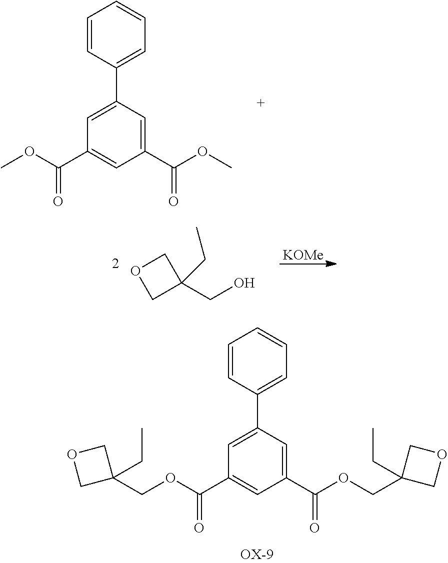

A procedure similar to Example 1 was used to make bis[(3-ethyl-3-oxetanyl)methyl]biphenyl-3,5-dicarboxylate, except that dimethyl biphenyl-3,5-dicarboxylate and TMPO were used as starting materials, affording the title compound in a 96% yield. The title compound was determined to have a melting point of 102° C. and an RI of 1.5568.

The title compound was characterized by NMR: ¹H NMR (CDCl₃, 250 MHz), δ (ppm): 8.65 (1H), 8.48 (2H), 7.67-7.41 (5H), 4.61-4.50 (12H), 1.93-1.85 (4H), 1.03-0.99 (6H).

### Example 6

### Aromatic Oxetane Ester Oligomers

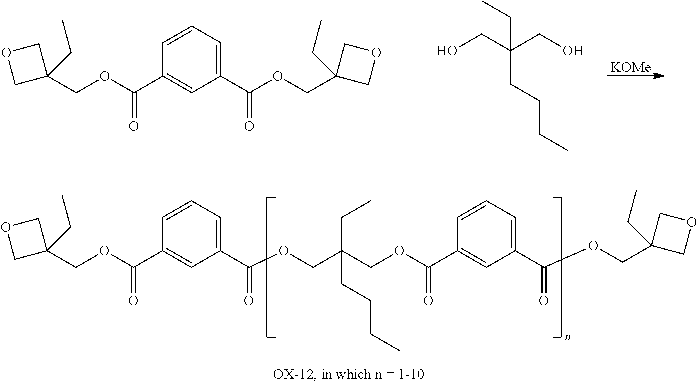

To a 250 mL flask was added 36.2 g of OX-3 (available from UBE Industries, Ltd., Japan under product name OXIPA), 8.0 g of butyl ethyl propanediol, and 0.051 g of KOMe. The reaction was allowed to continue under vacuum at a temperature of 70° C. for approximately 8 hours. The reaction was diluted with toluene and the remaining solids were filtered through a short silica column. A viscous oil was obtained after solvent removal.

The oligomeric product was characterized by MALDI-TOF-MS m/z: [M+Na]⁺ 675 (n=1), 965 (n=2), 1255 (n=3), 1545 (n=4), 1836 (n=5), 2126 (n=6), 2416 (n=7), 2706 (n=8), 2996 (n=9), 3286 (n=10).

### Example 7

### 3-Ethyl-3-oxetanylmethyl Benzoate

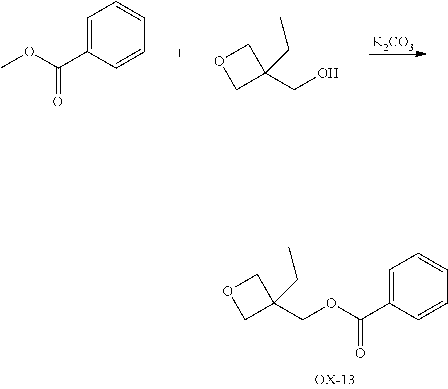

To a 250 mL flask was added 20.0 g of methyl benzoate, 18.75 g of TMPO, and 1.93 g of potassium carbonate. The reaction was allowed to continue under vacuum at a temperature of 70° C. for approximately 21 hours. The reaction was diluted with toluene and the solids were filtered. Vacuum distillation afforded 20.05 g of the title compound in a 62% yield.

The title compound was characterized by NMR: ¹H NMR (CDCl₃, 250 MHz), δ (ppm): 8.07-8.04 (2H), 7.61-7.42 (3H), 4.61-4.46 (6H), 1.90-1.81 (2H), 1.01-0.95 (3H).

The product was also characterized by direct injection APCI-MS m/z: [M+H]⁺ 221.

### Example 8

### Resorcinol Bis[(3-methyl-3-oxetanyl)methyl]Ether

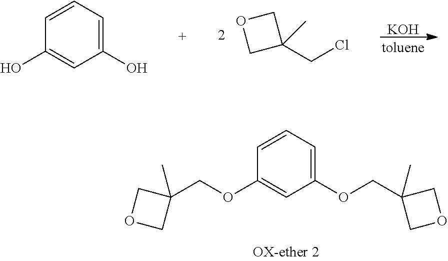

To a 250 mL flask, equipped with nitrogen purge, thermometer and magnetic stirrer, was added 10.0 g of resorcinol, 25.0 g of 3-(chloromethyl)-3-methyloxetane, 1.0 g of tetrabutyl ammonium bromide, 50 mL of toluene, and 11.2 g of KOH pellets. The reaction mixture was warmed to a temperature of 120° C. and stirred for a period of time of 24 hours, after which 50 mL of toluene was added. The solution was transferred to a separatory funnel, washed four times with 50 mL portions of deionized water, and dried over magnesium sulfate before evaporating the solvent thereby leaving a residue. The residue was vacuum distilled under 150-160° C./201 microns, such that a total of 11.7 g of a liquid was collected. Upon standing, the liquid crystallized to afford the title compound as a solid with a melting point of 71° C. in a 46% yield.

The product was characterized by NMR: ¹H NMR (CDCl₃, 250 MHz), δ (ppm): 7.22-7.17 (1H), 6.57-6.54 (3H), 4.63-4.61 (4H), 4.46-4.43 (4H), 4.01 (4H), 1.43 (6H).

### Syntheses of Carboxylic Acids

### Example 9

### Tetra Aromatic Acid

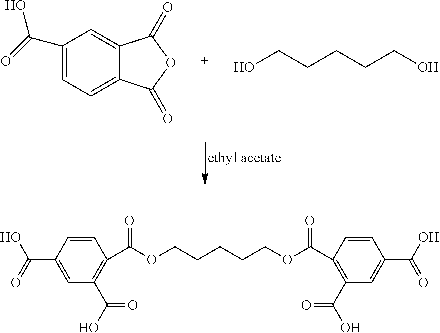 [SMILES: O=C(O)c1ccc2c(c1)C(=O)OC2=O ; OCCCCCO ; O=C(O)c1ccc(C(=O)OCCCCCOC(=O)c2ccc(C(=O)O)cc2C(=O)O)c(C(=O)O)c1]

To a 500 ml round bottom flask was added 19.2 g of trimellitic anhydride and ethyl acetate 200 ml. This mixture was stirred with a magnetic stir bar under nitrogen purge until a solution was achieved. The mixture was heated to reflux, and 5.2 g of 1,5-pentadiol in 25 ml ethyl acetate was introduced into the mixture dropwise over a period of time of approximately 30 minutes. The mixture was stirred continuously under reflux for another 6 hours. The ethyl acetate was then removed by vacuum to afford a white solid in a 94% yield. The solid had a melting point of approximately 187-192° C.

The product was characterized by NMR: ¹H NMR (CDCl₃, 250 MHz), δ (ppm): 8.05-8.15 (4H), 7.89-7.98 (2H), 4.32 (4H), 2.49 (4H), 1.23 (2H).

### Curing of Oxetane-Containing Compounds with Latent Carboxylic Acids

### Example 10

As latent carboxylic acids, anhydrides were chosen. Oxetane OX-1 (OXTP available commercially from UBE Industries, Ltd., Japan) was blended with a number of fine particle anhydride resins at 1:1 molar ratio (anhydride:oxetane=1:1, or anhydride+carboxylic acid:oxetane=1:1), and the mixtures heated at a temperature of 150° C. for a period of time of 2 hours. As shown below in Table 1, the compound having carboxylic acid and latent organic functionality on the same molecule—in this case, TMAn, which is an aromatic carboxylic acid with aromatic anhydride functionality on the same molecule—co-cured with the oxetane-containing compound. These results were validated by Differential Scanning Calorimetry (“DSC”) with a heating profile of 25-300° C. at 10° C./min.

The H-TMAn-containing sample, which is an aliphatic carboxylic acid with anhydride functionality on the same compound, cured above 180° C. with slight yellowing. (H-TMAn has a structure similar to TMAn except for the aromaticity.) A 1:1 molar blend of H-TMAn and OX-3 (anhydride+carboxylic acid:oxetane) showed a cure onset temperature at 188° C. and a peak temperature at 262° C., and a 1:1 molar blend of H-TMAn and OX-ether 1(anhydride+carboxylic acid : oxetane) showed a cure onset temperature of 178° C. and a peak temperature at 248° C.

The anhydride structure, cure conditions, and DSC results for Sample Nos. 1-5 are presented in Table 1.

TABLE 1

| | | | Cure | |
|---|---|---|---|---|
| Sample | | OX-1:Anh | 2 hrs @ | |
| No. | Anhydride Structure | (wt/gms) | 150° C. | DSC/Observations |
| 1 | 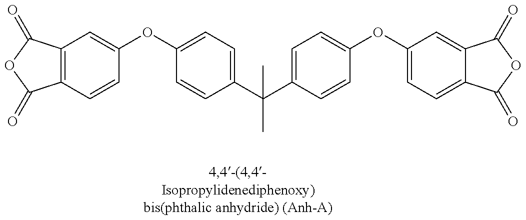 [SMILES: CC(C)(c1ccc(Oc2ccc3c(c2)C(=O)OC3=O)cc1)c1ccc(Oc2ccc3c(c2)C(=O)OC3=O)cc1] | 3.62:5.2 | Pre-melted at 180° C. for 15 min. No gelling. Soluble in THF after heating. | No curing exotherm observed. |
| 2 | 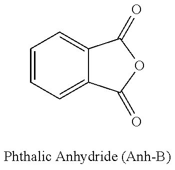 [SMILES: O=C1OC(=O)c2ccccc21] | 3.62:2.96 | No gelling. Soluble in THF after heating. | No curing exotherm observed. |
| 3 | 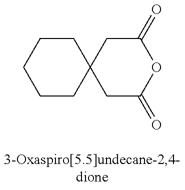 [SMILES: O=C1CC2(CCCCC2)CC(=O)O1] | 3.62:3.64 | No gelling. Recrystallized. | No curing exotherm observed. |
| 4 | 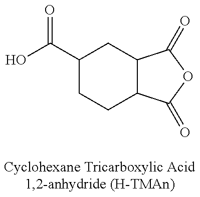 [SMILES: O=C(O)C1CCC2C(=O)OC(=O)C2C1] | 3.62:1.98 | No gelling. Soluble in THF after heating. Turned slightly yellow. | Major onset at 180° C., peak around 275° C. |
| 5 | 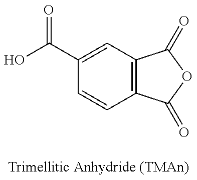 [SMILES: O=C(O)c1ccc2c(c1)C(=O)OC2=O] | 3.62:1.92 | Pre-melted at 180° C. for 15 min. Formed clear, hard and insoluble piece. | Major onset at 150° C., peak around 210° C. |

### Curing of Oxetane-Containing Compounds with Carboxylic Acids

### Example 11

A blend of 2.10 g of 1,2,4-benzenetricarboxylic acid powder and 5.43 g of OX-3 (OXIPA, UBE Industries Ltd., Japan) was prepared with mixing and cured at a temperature of 200° C. for a period of time of 1 hour in an aluminum pan. A clear, insoluble film was formed with yellowness index of 2.9 as determined by BYK CIE spectro-guide, using the aluminum pan as background. As a reference, the yellowness index of the standard BYK white background card was found to be 6.33.

### Curing of Oxetane-Containing Compounds with a Compound Containing Carboxylic Acid and Latent Carboxylic Acid Functional Groups

### Example 12

As a compound containing both carboxylic acid and latent carboxylic acid functional groups, TMAn was chosen. TMAn was blended with a number of aromatic oxetane-containing compounds at 1:1 molar ratio (anhydride+carboxylic acid:oxetane=1:1), and the mixtures heated first at a temperature of 180° C. for a period of time of 15 minutes, and then at a temperature of 150° C. for a period of time of 2 hours. Results are presented below in Table 2, where observations before and after cure for Sample Nos. 5-8 show that clear, transparent films were produced after cure.

TABLE 2

| Sample | | OX:TMAn | Before | After |
|---|---|---|---|---|
| No. | Oxetane Structure | (wt/grams) | Cure | Cure |
| 5 | 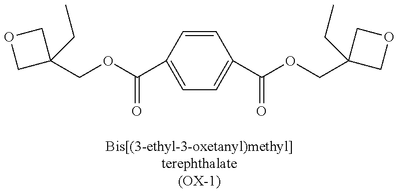 [SMILES: CCC1(COC(=O)c2ccc(C(=O)OCC3(CC)COC3)cc2)COC1] | 3.62:1.92 | White powder | Clear, hard film |
| 6 | 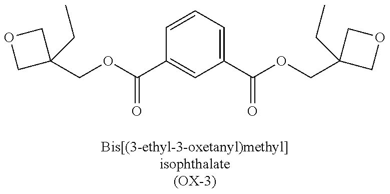 [SMILES: CCC1(COC(=O)c2cccc(C(=O)OCC3(CC)COC3)c2)COC1] | 3.62:1.92 | White paste | Clear, hard film |
| 7 | 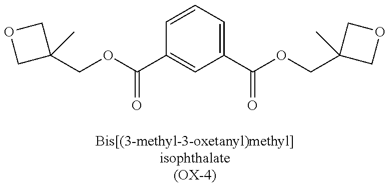 [SMILES: CC1(COC(=O)c2cccc(C(=O)OCC3(C)COC3)c2)COC1] | 3.34:1.92 | White powder | Clear, hard film |
| 8 | 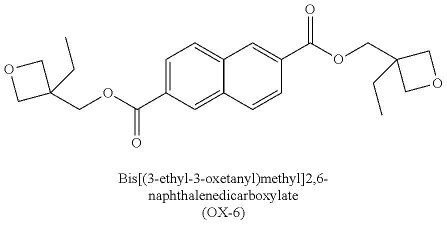 [SMILES: CCC1(COC(=O)c2ccc3cc(C(=O)OCC4(CC)COC4)ccc3c2)COC1] | 4.12:1.92 | White powder | Clear, hard film (cured at 180° C.) |

### Example 13

TMAn was blended with two oxetane-containing compounds, the aromatic oxetane ether resins OX-ether 1 and OX-ether 2 (both of which are clear, colorless resins) at 1:1 molar ratio (anhydride+carboxylic acid:oxetane=1:1), and the two mixtures heated in at a temperature of 150° C. for a period of time of 2 hours. OX-ether 1 was prepared in accordance with the procedures set forth in U.S. Pat. No. 7,902,305. OX-ether 2 was prepared as set forth above in Example 8.

As shown below in Table 3, in which results for Sample Nos. 9 and 10 are presented, both samples were found to produce opaque, yellow samples after cure.

TABLE 3

| Sample | | Oxetane:TMAn | Before | |
|---|---|---|---|---|
| No. | Oxetane Structure | (wt/grams) | Cure | After Cure |
| 9 | 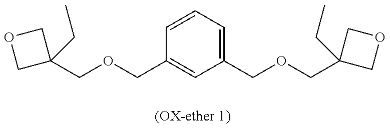 [SMILES: CCC1(COCc2cccc(COCC3(CC)COC3)c2)COC1] | 3.34:1.92 | White paste | Yellow opaque film, TMAn did not fully dissolve |
| 10 | 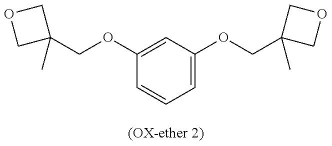 [SMILES: CC1(COc2cccc(OCC3(C)COC3)c2)COC1] | 2.78:1.92 | Yellow paste | Yellow opaque film, TMAn did not fully dissolve |

### Example 14

For comparative purposes, TMAn was blended with certain conventional epoxy resins (which are clear, colorless resins) at 1:1 molar ratio (anhydride+carboxylic acid:epoxy), and heated at a temperature of 150° C. for a period of time of 2 hours (except for Sample No. 14, which was cured at a temperature of 175° C. for a period of time of 30 minutes). Results are presented below in Table 4, where observations before and after cure for Sample Nos. 11-14 show that while the samples formed films, the films each exhibited a degree of yellowing.

TABLE 4

| Sample | | Epoxy:TMAn | | |
|---|---|---|---|---|
| No. | Epoxy Structure | (wt/grams) | Before Cure | After Cure |
| 11 | 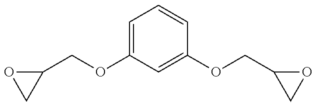 [SMILES: c1cc(OCC2CO2)cc(OCC2CO2)c1] | 2.22:1.92 | Yellow paste | Brown film |
| 12 | 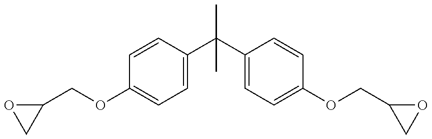 [SMILES: CC(C)(c1ccc(OCC2CO2)cc1)c1ccc(OCC2CO2)cc1] | 3.40:1.92 | Slightly yellow paste | Opaque yellow film |
| 13 | 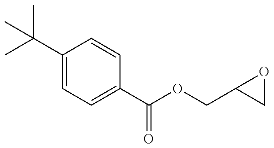 [SMILES: CC(C)(C)c1ccc(C(=O)OCC2CO2)cc1] | 4.68:1.92 | White paste | Clear, yellow film |
| 14 | 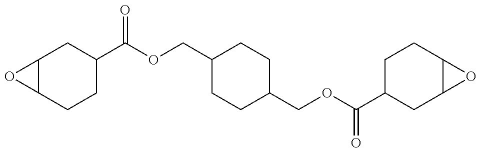 [SMILES: O=C(OCC1CCC(COC(=O)C2CCC3OC3C2)CC1)C1CCC2OC2C1] | 3.92:1.92 | White paste | Opaque yellow film |

### Example 15

Here we conducted thermal aging studies of reaction products of certain curable compositions of oxetane-containing compounds with a compound containing carboxylic acid and latent carboxylic acid functional groups. More specifically Sample Nos. 5 and 6 were each cured in a VWR aluminum dish (43 mm), and the yellowness index of each of the cured samples (with the aluminum dish as the substrate) was measured with a BYK CIE spectro-guide. The BYK white standard has a yellowness index of 6.33. The samples were heated at a temperature of 160° C. and periodic observations in changes of appearance were made. For instance, after 43 days, Sample No. 5 exhibited a change in the yellowness index from 1.44 to 7.34. This change, while seemingly large, remains close enough to the white standard to show almost no observable yellowing at all. Sample No. 6 exhibited a change in the yellowness index from 1.89 to 4.78, which is lower than the BYK white standard itself.

Sample Nos. 5 and 6 were also subjected to combined heat-photo aging. Here, the samples were first subjected to a temperature of 160° C. for a period of time of 10 days, followed by heat aging at a temperature of 170° C., while irradiating with 460 nm LED light. After 45 days of such exposure, Sample No. 5 exhibited a yellowness index of 7.82, which also shows only a very faint yellowing. Sample No. 6 exhibited a change in the yellowness index from 1.89 to 4.52, which is lower than the BYK white standard itself.

### Example 16

For comparative purposes, H-TMAn was blended with one of two commercially available epoxies, specifically cycloaliphatic ones: 3,4-epoxy-cyclohexylmethyl-3′,4′-epoxy-cyclohexanecarboxylate, sold under the product name Cyracure® UVR-6105 (Dow), and 1,4-cyclohexanedimethanol-3,4-epoxycyclohexanecarboxylic diester, sold under the product name S-60 (SynAsia) at a 1:1 molar ratio. A 2.5 g portion of each sample was cured in a VWR aluminum dish (43 mm), and the yellowness indexes of the samples (with the aluminum dish as substrate) were measured with a BYK CIE spectro-guide. The samples were exposed to a temperature of 160° C. and changes in yellowness index were monitored. For the UVR-6105/H-TMAn sample, the yellowness index was observed to increase from 1.00 to 11.31 after a period of time of 7 days, while the S-60/H-TMAn sample exhibited an increase in the yellowness index from 1.31 to 12.17.

### Example 17

In this example, onium salt catalysts were included in the curable compositions to determine the impact that the catalysts of cationic cure had on the cure profile. TMAn was blended with certain onium salt catalysts in a by weight in grams amount, as shown below in Table 5 to form Sample Nos. 5, 15 and 16, and DSC scans were conducted from 0-250° C. at 10° C. per minute under nitrogen. Both onium salt catalysts improved curing by reducing the onset and peak curing temperature. However, when these formulations catalyzed with onium salt were cured in an oven at 180° C. for 15 minutes, then at 150° C. for two hours, yellow samples were obtained.

TABLE 5

| | | | Tetrabutyl | Tetrabutyl | DSC | DSC | |
|---|---|---|---|---|---|---|---|
| Sample | | | ammonium | phosphonium | Tonset | Tpeak | |
| No. | OX-1 | TMAn | bromide | bromide | (° C.) | (° C.) | Color |
| 5 | 3.62 | 1.92 | | | 153 | 207 | Clear |
| 15 | 3.62 | 1.92 | 0.2 | | 136 | 199 | Yellow |
| 16 | 3.62 | 1.92 | | 0.2 | 133 | 199 | Yellow |

### Example 18

In this example, performance properties desirable for LEDs, such as barrier sealing by way of water vapor transmission rates, and percent transmission after aging under elevated temperature conditions and exposure to UV exposure are presented for a variety of curable compositions, including two commercially available ones presently used as encapsulants for LED assembly. The water vapor transmission rate was measured at a temperature of 50° C. at a relative humidity of 100% relative humidity using a MOCON PERMATRAN-W 3/33. The unit of measure is gm*cm/[m²*day].

Tables 6a and 6b, and 7a and 7b below present the constituents of the samples evaluated and the performance, respectively. In Tables 6a and 6b, the following abbreviations are used: OXIPA=Bis[(3-ethyl-3-oxetanyl)methyl]isophthalate; MBAOE=3-Ethyl-3-oxetanylmethyl 4-methylbenzoate; TMAn=Trimellitic anhydride; PMDA=Pyromellitic dianhydride; TMAn-4E=Trimellitic anhydride butyl ester; MHHPA=Methyl-1,2-cyclohexanedicarboxylic anhydride, mixture of isomers; PD=1,5-Pentane diol; CPL=e-caprolactone; Sn(Oct)₂=Tin(II) 2-ethylhexanoate; Zn(Oct)₂=BiCAT 3228 (Shepherd Chemical Company, Norwood, Ohio); BEOMS=Bis[(3-ethyl-3-oxetanyl)methyl sebacate; TMA=Trimellitic acid; and Tetra acid=reaction product of TMAn and 1,5-pentadiol. In Table 6b, the commercial cycloaliphatic epoxy-containing product is STYCAST 9XR-SUV from Henkel Corporation and the commercial silicone-containing product is OE6631 from Dow Corning Corporation.

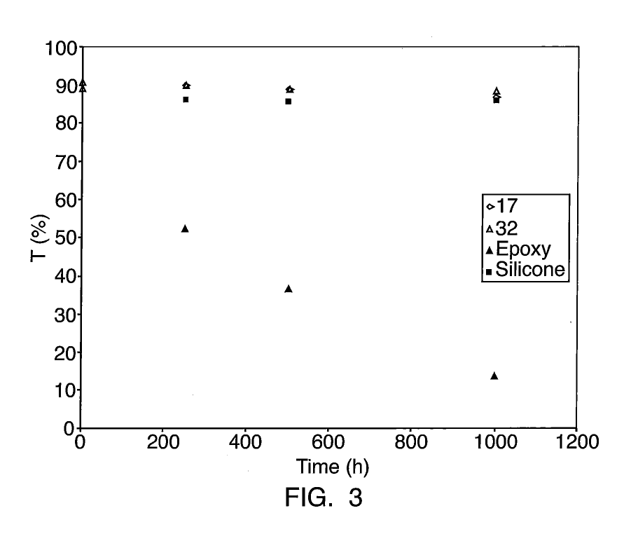

All samples set forth in Tables 6a and 6b were cured at a temperature of 150° C. for a period of time of 2 hours, followed by an increased temperature of 175° C. for an additional 20 minute time period, except for Sample No. 36, which was cured at a temperature of 175° C. for a period of time of 2 hours, and the commercially available silicone-containing product, which was cured at successive 1 hour time period intervals at temperatures of 80° C., 120° C., and 160° C. Reference to FIG. 3 shows a plot of time against percent transmission, where Sample Nos. 17 and 32 are presented as are the commercially available epoxy-containing composition and the commercially available silicon-containing composition. It can be readily seen that over time the percent transmission decreases steadily for the epoxy-containing composition, whereas for the commercially available silicon-containing composition it does not. Indeed, the two compositions based on the present invention (Sample Nos. 17 and 32) illustrated in FIG. 3 behaved more like the commercially available silicon-containing composition in this respect than the commercially available epoxy-containing composition. These two compositions possessed superior physical properties in other areas to the commercially available silicon-containing composition, as may be seen with reference to Tables 7a and 7b.

TABLE 6a

| | Sample No./Amt (wt %) | | | | | | | | | | | | | |
|---|---|---|---|---|---|---|---|---|---|---|---|---|---|---|
| Constituents | 17 | 18 | 19 | 20 | 21 | 22 | 23 | 24 | 25 | 26 | 27 | 28 | 29 | 30 |
| OXIPA | 3.27 | 3.27 | 3.27 | 6.50 | 3.27 | 18.1 | 18.1 | 3.84 | 5.5 | 3.84 | 5.5 | 3.84 | 5.00 | 1.81 |
| MBAOE | | | | | | | | | 5 | | 5.0 | | 5.00 | |
| TMAn | 1.73 | 1.73 | 1.73 | 3.4 | 1.73 | 9.6 | 4.8 | 1.92 | 2.1 | 1.92 | 2.1 | 1.92 | 2.11 | |
| Anh-A | | | | | | | 26 | | 5.7 | | 5.7 | | | 2.60 |
| PMDA | | | | | | | | | | | | | 2.40 | |
| TMAn-4E | | | | | | | | 0.30 | | 0.30 | | 0.30 | | |
| Sn(Oct)₂ | | | | | 0.0025 | | | | | | | | | |
| Zn(Oct)₂ | | 0.0025 | | | | 0.029 | | | 0.003 | 0.003 | 0.003 | 0.003 | 0.016 | 0.001 |
| PD | | | 0.25 | | 0.25 | 1.4 | | | | | 1.2 | 0.30 | | |
| CAPA2047A | | | | | | | | | | | | | 0.410 | |
| CPL | | | | 0.5 | | | | | | | | | | |

TABLE 6b

| | Sample No./Amt. (wt %) | | | | | | | | | |
|---|---|---|---|---|---|---|---|---|---|---|
| Constituents | 31 | 32 | 33 | 34 | 35 | 36 | 37 | 38 | 39 | 40 |
| OXIPA | 1.81 | 1.81 | 10.0 | 10.1 | 10.1 | 18.1 | 1.81 | 1.81 | | |
| BEOMS | | | | | | | | 2 | 2 | 2 |
| TMAn | | | 4.82 | 4.82 | 4.82 | | | | 1.91 | 1.91 |
| Anh-A | 2.6 | 2.6 | | | | | | 1.30 | | |
| MHHPA | | | 0.85 | 0.85 | 0.85 | | | | | |
| TMA | | | | | | 7.0 | | | | |
| Tetra acid | | | | | | | 2.44 | 2.44 | | |
| PD | 0.2 | 0.4 | | | | | | | | |
| CAPA2047A* | | | | | 0.41 | | | | | |
| Zn(Oct)₂ | | 0.02 | | 0.016 | 0.016 | | | | | |

*Polycaprolactone based diol available commercially from Perstorp Polyols, Inc., Toledo, OH.

TABLE 7a
Physical Property

| | | Sample No. | | | | | | | | | | | | | |
|---|---|---|---|---|---|---|---|---|---|---|---|---|---|---|---|
| | | 17 | 18 | 19 | 20 | 21 | 22 | 23 | 24 | 25 | 26 | 27 | 28 | 29 | 30 |
| WVTR | | 0.37 | 0.52 | 0.65 | | 0.54 | | | 0.50 | | 0.38 | | 0.41 | | |
| Ageing | | | | | | | | | | | | | | | |
| @ 150° C. | T % | | | | | | | | | | | | | | |
| (hours) | (nm) | | | | | | | | | | | | | | |
| 0 | 400 | 88.4 | 88.3 | 88.3 | 89.4 | 88.5 | 85.0 | 67.8 | 87.7 | 82..5 | 87.5 | 86.0 | 86.3 | 82.1 | 56.0 |
| | 450 | 90.1 | 90.0 | 90.3 | 90.6 | 89.9 | 88.6 | 85.5 | 89.2 | 87.5 | 89.5 | 89.2 | 87.5 | 87.7 | 86.0 |
| 250 | 400 | 86.3 | 85.5 | 81.9 | 83.6 | 83.6 | 82.6 | 70.7 | 86.2 | 82.6 | 86.2 | 84.5 | 83.2 | 79.9 | 66.7 |
| | 450 | 89.7 | 89.4 | 88.5 | 87.2 | 88.2 | 86.4 | 88.4 | 89.5 | 87.3 | 89.5 | 88.8 | 88.6 | 87.1 | 86.0 |
| 500 | 400 | 82.5 | 80.3 | 73.2 | 81.5 | 80.4 | 80.3 | 67.2 | 83.3 | 82.3 | 83.1 | 85.3 | 76.2 | 76.5 | 65.2 |
| | 450 | 88.8 | 87.4 | 84.2 | 83.2 | 88.0 | 84.6 | 86.4 | 89.1 | 87.3 | 88.6 | 88.8 | 87.0 | 86.8 | 85.7 |
| 1000 | 400 | 76.4 | 74.0 | 66.8 | 62.4 | 72.1 | 69.0 | 62.4 | 77.8 | 80.5 | 77.5 | 80.1 | 71.3 | 60.82 | 61.4 |
| | 450 | 86.7 | 85.6 | 83.5 | 78.5 | 85.0 | 82.5 | 81.5 | 87.1 | 85.4 | 86.7 | 86.9 | 85.6 | 81.83 | 84.9 |

TABLE 7b
Physical Property

| | | Sample No. | | | | | | | | | | |
|---|---|---|---|---|---|---|---|---|---|---|---|---|
| WVTR | | 31 | 32 | 33 | 34 | 35 | 36 | 37 | 38 | 39 | Epoxy | Silicone |
| Ageing@ | | | | | | | | | | | | 2.94 |
| 150° C. | T % | | | | | | | | | | | |
| (hours) | (nm) | | | | | | | | | | | |
| 0 | 400 | 80.5 | 85.1 | 85 | 83.8 | 84 | 85.6 | 86.4 | 88.9 | 87.4 | 67.9 | 88.2 |
| | 450 | 86.5 | 89.2 | 89.2 | 89.5 | 89.1 | 87.6 | 89.2 | 90.1 | 89.6 | 90.5 | 88.9 |
| 250 | 400 | 82.5 | 86.8 | 81.8 | 79.4 | 78.9 | 65.2 | 84.2 | 84.1 | 79.2 | 20.6 | 80.9 |
| | 450 | 88 | 90 | 88.1 | 87.9 | 86.5 | 81.5 | 88.7 | 88.2 | 82.5 | 52.3 | 86.1 |
| 500 | 400 | 74.5 | 85.4 | 78.7 | 73.5 | 75.1 | 56.2 | 82.5 | 81.2 | 70.1 | 8.79 | 79.3 |
| | 450 | 86 | 88.9 | 87.1 | 85.6 | 85.5 | 78.8 | 86.7 | 85.7 | 76.5 | 36.5 | 85.6 |
| 1000 | 400 | 72.5 | 83.1 | 67.05 | 58.02 | 61.26 | 45.2 | 71.2 | 68.9 | 46.6 | 0.89 | 78.6 |
| | 450 | 85.2 | 88.2 | 83 | 79.58 | 80.66 | 74.7 | 82.7 | 80.1 | 73.1 | 13.7 | 85.8 |

### Example 19

An LED device with an EPISTAR ES-CABLV45C LED chip (460 nm peak wavelength) and a PPA reflector cup was encapsulated with different encapsulant materials and its light output was measured. Before encapsulation, the radiant power of the individual LED devices was measured. The reflector cup was then filled with different encapsulant materials and cured. The radiant power of the encapsulated devices was measured again and compared with that of the un-encapsulated device. This comparison gives the relative radiant output in percentage, which is an indication of the effect of encapsulant on light extraction of the device. Here, Sample No. 17 was compared with STYCAST 9XR-SUV from Henkel and OE6631 from Dow Corning. Three LED devices were encapsulated and the average relative radiant output was reported. Sample No. 17 affords a relative radiant output of 108% after curing. In comparison, the relative radiant outputs for STYCAST 9XR-SUV and OE6631 were 106% and 109%, respectively.

### Example 20

In this example, BiCAT Z (Shepherd Chemical) was mixed with 7.24 g of OXTP at a temperature of about 100° C. The mixture was cooled to room temperature and ground into a fine powder. This powder was mixed with 3.84 g of TMAn to obtain a free-flowing compound. The compound was then pressed into tablets with ½″ diameter in a mold with 1 ton of pressure in a hydraulic press at room temperature. One tablet was pressed between the two platens of a pre-heated hot press. At a temperature of 195° C., when the platens were opened after 5 minutes, a clear hard disc was obtained. The disc was post mold cured at a temperature of 150° C. for a period of time of 2 hours to obtain fully cured material. This example demonstrates the feasibility of the current invention to be used in transfer molding process for reflector cup or remote phosphor component manufacturing.

1. A curable composition comprising at least one oxetane-containing compound and at least one of a carboxylic acid, a latent carboxylic acid, compounds having at least one carboxylic acid functionality and at least one latent carboxylic acid functionality, or mixtures thereof.

2. The composition of claim 1, wherein the oxetane-containing compound comprises at least one oxetane functionality and at least one latent carboxylic acid functionality.

3. The composition of claim 1, further comprising a catalyst.

4. The composition of claim 1, wherein the oxetane-containing compound is an aromatic oxetane-containing compound.

5. The composition of claim 1, wherein the oxetane-containing compound has at least one oxetane ester functional group attached to an aromatic substrate or an aliphatic substrate.

6. (canceled)

7. The composition of claim 1, wherein the carboxylic acid is an aromatic carboxylic acid or an aliphatic carboxylic acid.

8. (canceled)

9. The composition of claim 1, wherein the latent carboxylic acid is an aromatic latent carboxylic acid or an aliphatic latent carboxylic acid.

10. (canceled)

11. The composition of claim 1, wherein the latent carboxylic acid is an aliphatic anhydride or an aromatic anhydride.

12. (canceled)

13. The composition of claim 1, wherein the oxetane-containing compound and the carboxylic acid or the latent carboxylic acid are present in a molar ratio of about 0.7 to about 1:3.

14. The composition of claim 1, wherein the carboxylic acid and the latent carboxylic acid are each present on the oxetane-containing compound.

15. (canceled)

16. The composition of claim 3, wherein the catalyst is selected from zinc-containing catalysts, bismuth-containing catalysts, tin-containing catalyst, and combinations thereof.

17. (canceled)

18. The composition of claim 1, further comprising an alcohol compound.

19. The composition of claim 1, further comprising a co-reactant selected from the group consisting of oxiranes, thiiranes, and thiooxetanes.

20. (canceled)

21. The composition of claim 1, wherein the oxetane-containing compound has the following structure, in which R is a methyl or ethyl group and Ar is an aromatic group:

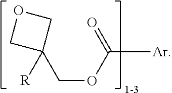

22. The composition of claim 1, wherein the oxetane-containing compound is selected from one or more of:

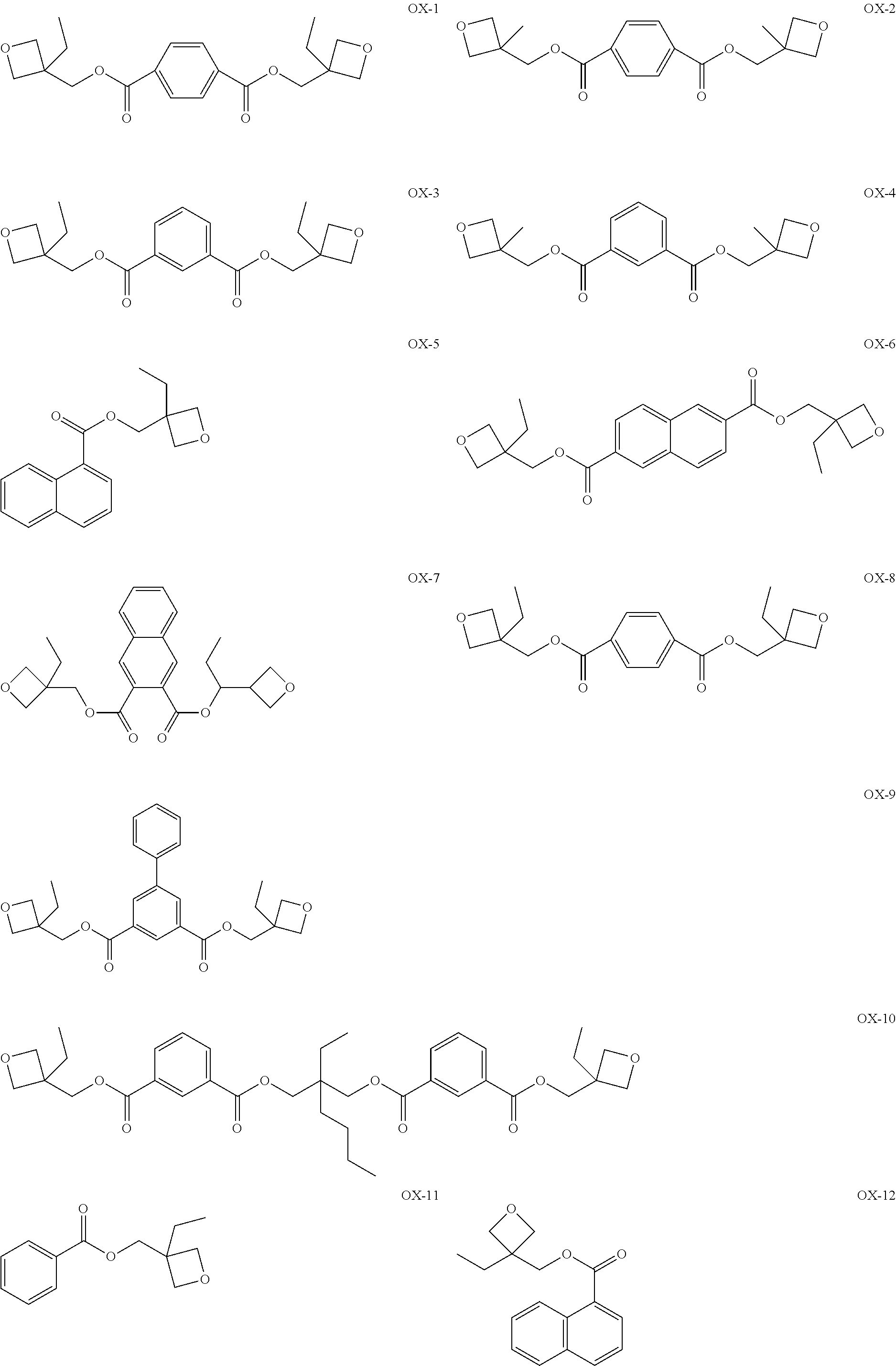

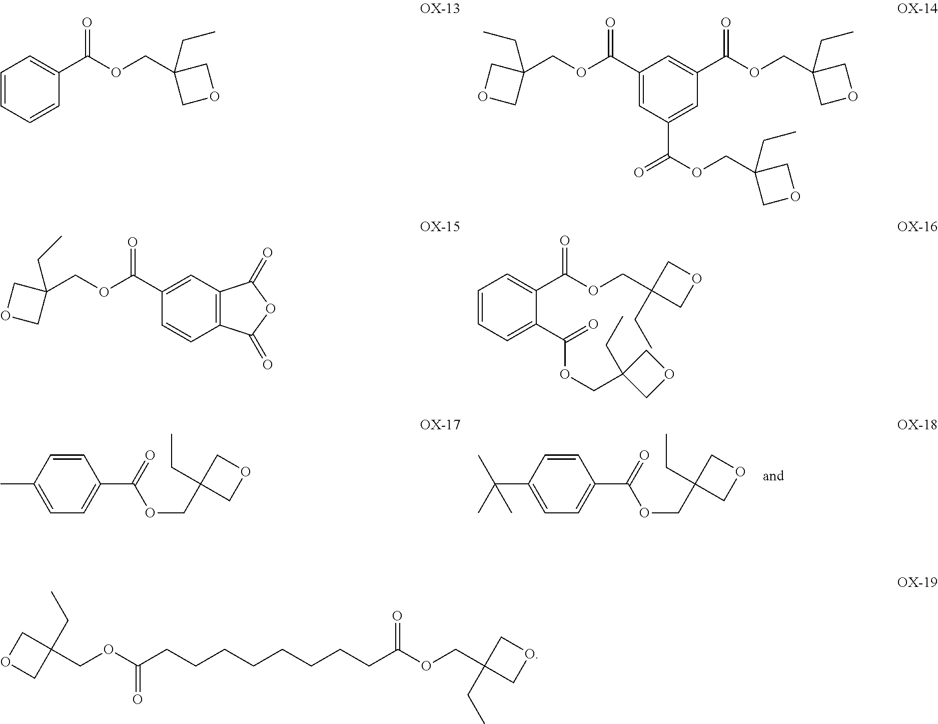

23. The composition of claim 7, wherein the aromatic carboxylic acid is selected from the group consisting of benzoic acid, terephthalic acid, phthalic acid, isophthalic acid, 1,2,4-benzenetricarboxylic acid, trimesic acid, naphthoic acid, isomers of naphthalenedicarboxylic acid and an adduct of TMAn and a diol.

24. The composition of claim 7, wherein the compound having carboxylic acid and latent carboxylic functionality is selected from the group consisting of

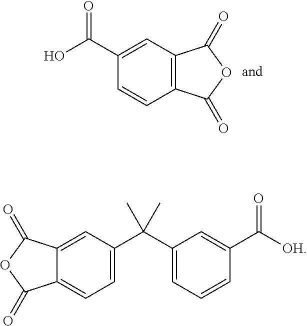 [SMILES: O=C(O)c1ccc2c(c1)C(=O)OC2=O ; CC(C)(c1cccc(C(=O)O)c1)c1ccc2c(c1)C(=O)OC2=O]

25. The composition of claim 1, wherein the latent carboxylic acid is selected from the group consisting of

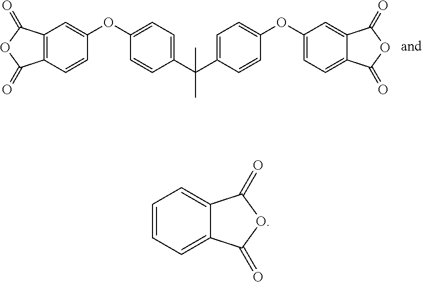 [SMILES: CC(C)(c1ccc(Oc2ccc3c(c2)C(=O)OC3=O)cc1)c1ccc(Oc2ccc3c(c2)C(=O)OC3=O)cc1 ; O=C1OC(=O)c2ccccc21]

26. The composition of claim 7, wherein the aliphatic carboxylic acid is cyclohexane tricarboxylic acid 1,2-anhydride.

27. A LED device comprising:
a substrate on which is electrically connected a LED over and/or around which is formed an encapsulant comprising a reaction product of an oxetane-containing compound and an carboxylic acid, a latent carboxylic acid, compounds having at least one carboxylic acid functionality and at least one latent carboxylic acid functionality, or mixtures thereof.

28. The LED assembly of claim 27, further comprising a reflector element dimensioned and disposed to be positioned around the LED.

29. The LED assembly of claim 27, further comprising a lens.

30. The LED assembly of claim 27, wherein the encapsulant further comprises phosphor.

31. A reflector for an LED assembly comprising a reaction product of an oxetane-containing compound and an carboxylic acid, a latent carboxylic acid, compounds having at least one carboxylic acid functionality and at least one latent carboxylic acid functionality, or mixtures thereof.

32. The reflector of claim 31, further comprising a reflective element.

33. A lens for an LED assembly comprising a reaction product of an oxetane-containing compound and a carboxylic acid, a latent carboxylic acid, compounds having at least one carboxylic acid functionality and at least one latent carboxylic acid functionality, or mixtures thereof.

34. A composition comprising phosphor and an oxetane-containing compound and a carboxylic acid or a latent carboxylic acid, a latent carboxylic acid, compounds having at least one carboxylic acid functionality and at least one latent carboxylic acid functionality, or mixtures thereof.

35-36. (canceled)

37. A method of manufacturing an encapsulant composition for an LED assembly, steps of which comprise
providing one or more oxetane-containing compounds; and
providing at least one of an carboxylic acid, a latent carboxylic acid, compounds having at least one carboxylic acid functionality and at least one latent carboxylic acid functionality, or mixtures thereof,
wherein the encapsulant composition when cured at a temperature of 25° C. to 200° C. for a period of time of about 1 to about 2 hours demonstrates an initial transparency of at least about 85% and a percent transparency decrease of about 10% after exposure to a temperature of 150° C. for a period of time of 1,000 hours as measured by UV/VIS spectrophotometer at 450 nm; thermal stability after exposure to 150° C. for a period of time of 500 hours in terms of yellowing of less than 10 as measured by BYK CIE spectro-guide or a percent transmission decrease of less than about 10%; has a refractive index of greater than 1.5; and barrier properties of less than 2 g*cm/[m²*day] measured by water vapor transmission rates at 50° C. at a relative humidity of 100% using a MOCON PERMATRAN-W-3/33.

38. The method of claim 37, wherein the percent transparency decrease is measured after exposure to a temperature of 150° C. for a period of time of 1,000 hours.

39-43. (canceled)
